(19) United States
(12) Patent Application Publication
(10) Pub. No.: US 2016/0178669 A1
(43) Pub. Date: Jun. 23, 2016

(54) Circuit for Determining Load Type of a Serially Connected Electrical AC Load and Related Method

(71) Applicant: David Rothenberger, Winnipeg (CA)

(72) Inventor: David Rothenberger, Winnipeg (CA)

(21) Appl. No.: 14/576,998

(22) Filed: Dec. 19, 2014

(51) Int. Cl. G01R 15/00

(52) U.S. Cl. CPC G01R 15/002

(57) ABSTRACT

A circuit for determining load type of an electrical AC load that is receiving power from an AC power source through an AC power line features an electronic switch connected in series between the AC power source and the AC load. The circuit also features a triggering device, which provides a trigger signal to the electronic switch, and a measuring device, which obtains a reading of a voltage across the terminals of the electronic switch. The components of the circuit are arranged so that, within an AC half cycle, the trigger signal effects the electronic switch to progress through one conduction cycle. After an end of the AC half cycle, the measuring device obtains the reading, which has a value based on which the load type of the AC load is determined. A related method for determining the load type is also disclosed.

### FIELD OF THE INVENTION

The present invention relates generally to a circuit for delivering power to electrical AC loads through an electronic switch, and more particularly the present invention relates to a circuit which is arranged to detect load type of the AC load based on voltage-current characteristics of same.

### BACKGROUND

Phase-delayed power is a common technique used to vary power delivered to an electrical AC load by introducing a phase angle into power delivered to the AC load. One way in which the phase angle can be introduced is by delivering the power through an electronic switch and consequently controlling when the electronic switch conducts current.

Controlling the amount of power delivered to an AC load by means of phase delay can be performed on predominantly resistive loads. For example, applying phase-delayed power to an incandescent bulb in a dimmer control application may be desirable because the dimmer control has a pleasing aesthetic quality. However, reducing the power delivered to a predominantly reactive load, i.e., predominantly non-resistive load, such as a compact fluorescent light (CFL) or a fluorescent tube using the aforementioned technique will not work. In fact, the effect of using a dimmer control (more generally phase-delayed power) on an inappropriate load can damage or destroy the electronic switch and or the AC load itself.

U.S. Pat. No. 7,973,589 (Rothenberger) describes a two wire no touch light switch which was developed to address the need to control the AC load without needing to physically touch the light switch or to rewire the existing in-building AC network. The light switch was developed to be a single pole-single throw (SPST) two wire mechanical switch replacement. The light switch is connected in series with the load and is able to both derive sufficient power to operate circuitry of the light switch while passing more than 99% of power available to the AC load when conducting current in a conductive state and consume less than a few milliwatts when not conducting current in a high impedance state. If this light switch is also to operate as a dimmer, the light switch requires information to determine whether the load is of the appropriate type to receive phase-delayed power. Historically, package labeling of the AC load and prominent instructions thereof were replied upon to advise a user which types of loads would work.

Applicant has developed a unique solution that may be incorporated into the patented Rothenberger light switch or other devices with dimming or other phase-delayed power functions.

### SUMMARY OF THE INVENTION

According to one aspect of the invention there is provided a circuit for determining load type of an electrical AC load that is receiving power from an AC power source through an AC power line, the circuit comprising:
an electronic switch connected in series between the AC power source and the AC load;
a triggering device configured to provide a trigger signal to switch said electronic switch to a conductive state; and
a measuring device arranged to obtain a reading of a monitored condition that is indicative of a voltage across terminals of the electronic switch;
wherein the triggering device is arranged to, within an AC half cycle of a voltage of the AC power source, initiate the trigger signal proximate a first zero crossing of the AC half cycle so as to deliver power to the AC load through said electronic switch, subsequently terminate the trigger signal in advance of a subsequent zero crossing of the AC half cycle so that the electronic switch will be switched to a high impedance state when a current level through the electronic switch drops to a value below a minimum level required to maintain the electronic switch in the conductive state; and
wherein the measuring device is arranged to obtain the reading after said subsequent zero crossing, the reading having a value based on which the load type of the AC load is determined.

The embodiment of the invention as described hereinafter provides a systematic means to determine the load type of a serially connected AC load using an electronic switch, in which load type refers to electrical characteristics of the AC load being predominantly resistive or predominantly reactive (i.e., a dominant part of the impedance of the AC load is imaginary). Consequently, the determination of the load type could be used to prevent dimmer switches from applying a phase altered AC source to a load which is inappropriate and cannot tolerate the phase delayed AC power, and as such the method minimizes the risk of damaging or destroying the light switch circuit or the AC load.

Preferably, the monitored condition is a voltage across the terminals of the electronic switch.

Preferably, the circuit further includes a timer configured to measure a predetermined time interval, an expiration of which initiates the reading taken by the measuring device. It is preferred that the predetermined time interval is sufficiently long so that the expiration of the predetermined time interval is after said subsequent zero crossing. Preferably, the predetermined time interval is shorter than three-halves of a duration of the AC half cycle. In one embodiment, the predetermined time interval is shorter than eleven-eighths of a duration of the AC half cycle. It is preferred that the triggering device is arranged to initiate the trigger signal at a start of the predetermined time interval. Preferably, the triggering device is arranged to terminate the trigger signal in advance of the expiration of the predetermined time interval.

Preferably, the triggering device is arranged to sustain the trigger signal for at least one-eighth of the AC half cycle.

Preferably, the triggering device is arranged to initiate the trigger signal at the first zero crossing of the AC half cycle.

Preferably, the triggering device is arranged to terminate the trigger signal approximately halfway through the AC half cycle so as have the electronic switch conduct in a first direction of current flow only within a conduction cycle of the electronic switch.

Preferably, the circuit further includes a computing device which comprises a processor and a computer readable memory coupled to said processor and having stored thereon statements and instructions for execution by the process that, when executed, perform a test routine which includes a step of determining the load type based on the value of the reading. It is preferred that the computer readable memory and the statements and instructions stored thereon are configured to include a timer function in the test routine that measures a predetermined time interval, and a measurement function that is initiated by expiry of the predetermined time interval to obtain the reading.

According to a second aspect of the invention there is provided a method for determining load type of an electrical AC load that is receiving power from an AC power source through an AC power line in a circuit, the circuit further comprising an electronic switch which is connected in series between the AC power source and the AC load; a triggering device; and a measuring device; the method comprising the following steps:
within an AC half cycle of a voltage of the AC power source,
   initiating a trigger signal of the triggering device proximate a first zero crossing of the AC half cycle, the trigger signal switching the electronic switch to a conductive state so as to deliver power to the AC load through said electronic switch;
   terminating the trigger signal before a subsequent zero crossing of the AC half cycle so that the electronic switch will be switched to a high impedance state when a current level through the electronic switch drops to a value below a minimum level required to maintain the electronic switch in the conductive state;
after said subsequent zero crossing, obtaining a reading of a monitored condition that is indicative of a voltage across terminals of the electronic switch;
based on the reading, determining the load type of the AC load.

Preferably, the step of determining the load type comprises comparing the reading to a range of values around an expected value for a predominantly resistive load, the range of values spanning from a lower range limit below the expected value and an upper range limit above the expected value. A value of the reading near zero confidently indicates a predominantly inductive load, and the value of the reading being significantly greater than the expected value confidently indicates a predominantly capacitive load. Accordingly, it is preferable that the lower range limit is closer to zero than to the expected value, and preferably the upper range limit is at least one-and-a-half times the expected value. Upon finding that the reading has a value which lies within the range of values, the load type is identified as predominantly resistive. Optionally, when said electronic switch is operable to deliver phase-delayed power to the AC load in a first mode of operation, and having determined that the load type is predominantly resistive, the method further comprises the step of switching to the first mode of operation. Upon finding that the reading has a value that lies outside said range of values, the load type is identified as predominantly reactive. Optionally, when said electronic switch is operable to deliver phase-delayed power to the AC load in a first mode of operation, but not in a second mode of operation, and having determined that the load type is predominantly reactive, the method further comprises the step of switching into to the second mode of operation. In the instance that the value of the reading has a magnitude that exceeds the upper range limit, the load type is identified as predominantly capacitive. In the instance that the value of the reading has a magnitude below the lower range limit, the load type is identified as predominantly inductive.

Preferably, the triggering device sustains the trigger signal for at least one-eighth of a duration of the AC half cycle.

### BRIEF DESCRIPTION OF THE DRAWINGS

One embodiment of the invention will now be described in conjunction with the accompanying drawings in which:

FIG. 1 is a circuit which can be used to determine the load type of an unknown AC load that uses a triac as the electronic switch connected in series between the AC power source and the AC load.

FIG. 2a is a voltage waveform of an AC power source in the circuit of FIG. 1 that shows timing of events which are used to determine the load type of the unknown AC load.

FIG. 2b is a waveform of the voltage across terminals of the triac in FIG. 1 when the unknown AC load is predominantly resistive, that is synchronised with the voltage waveform of the AC power source in FIG. 2a.

FIG. 2c is a waveform of the voltage across the triac as in FIG. 2b when the unknown load is predominantly inductive.

FIG. 2d is a waveform of the voltage across the triac as in FIG. 2b when the unknown load is predominantly capacitive.

In the drawings like characters of reference indicate corresponding parts in the different figures.

### DETAILED DESCRIPTION

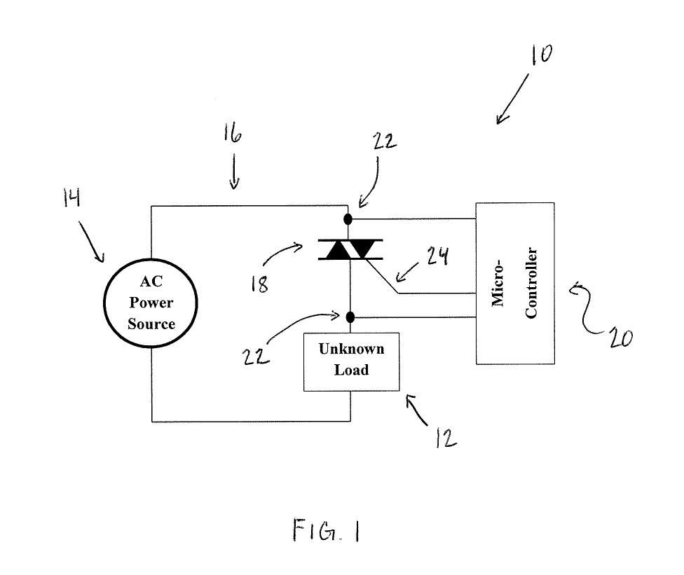

Referring to the accompanying figures, there is illustrated in FIG. 1 a circuit 10 for determining load type of an electrical AC load 12 that is receiving power from an AC power source 14 through an AC power line 16. One example of an application of the circuit 10 is in dimmer control to vary power to household loads, examples thereof which include but are not limited to light fixtures. Light fixtures having incandescent bulbs mounted therein are able to tolerate phase-delayed power; in contrast, compact fluorescent lights (CFLs) and fluorescent tubes cannot tolerate phase-delayed power. The example related to CFLs and fluorescent tubes will be described hereinafter in regards to the preferred embodiment of the invention.

The circuit 10 has a triac 18, which is an electronic switch, connected in series between the AC power source 14 and the AC load 12. The triac is able to conduct current in both directions of current flow because the circuit is intended to be used as part of a conventional AC network of a building; however, in general, the electronic switch has to be able to conduct current in at least one direction of current flow in order for the circuit to be used strictly as a test circuit for determining the load type of the AC load 12.

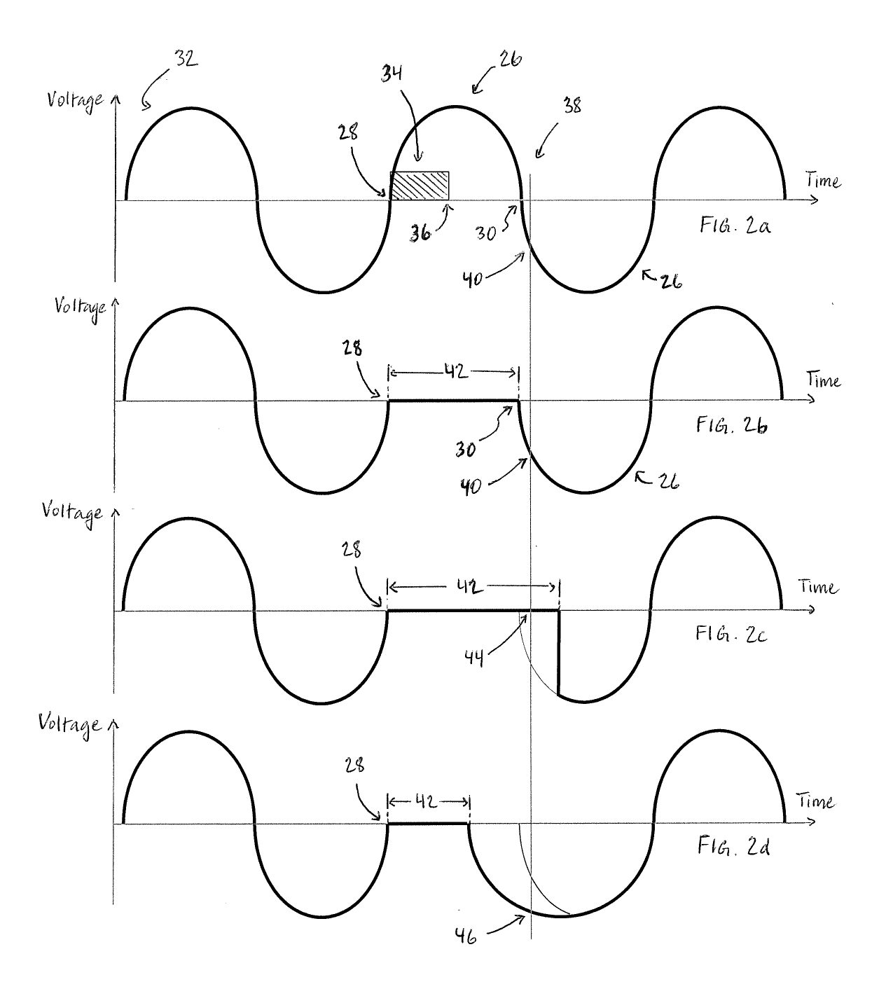

The circuit 10 further includes a microcontroller 20 which is coupled to the triac 18. Generally speaking, the microcontroller is a computing device comprising a processor and a computer readable memory coupled to the processor. The computer readable memory has stored thereon statements and instructions for execution by the processor. The microcontroller also has a set of inputs and outputs which are used to interface with the triac and a measuring device which is a peripheral device of the microcontroller. The measuring device is arranged to monitor a condition that is indicative of a voltage across terminals 22 of the triac. As such, the microcontroller is programmed with the following functions in the preferred embodiment: (i) a triggering function which provides a trigger signal to a gate 24 of the triac 18 to switch same to a conductive state; (ii) a measurement function to capture a reading of the monitored condition from the measuring device; and (iii) a timer function serving as a timer that measures a predetermined time interval. The monitored condition is the voltage across the terminals 24 of the triac in the preferred embodiment because same is a practical measurement that can be obtained within the circuit 10. Accordingly, inputs of the measuring device are coupled to the respective terminals of the triac, and an output of the microcontroller 20 is connected to the gate 24 of the triac. Furthermore, the predetermined time interval has a duration of 8.70 milliseconds, which is 0.37 milliseconds longer than a duration of an AC half cycle 26 at a frequency of 60 Hz. Such an AC half cycle is illustrated in FIG. 2a, from a first zero crossing 28 of the AC half cycle to a subsequent zero crossing 30 thereof.

In use, the circuit 10 is a main hardware component in a test procedure to determine the load type. The test procedure is managed by the microcontroller 20, which is programmed with a test routine that executes the test procedure described in more detail hereinafter.

The following takes place within the AC half cycle 26 of a voltage waveform 32 of the AC power source 14 and is clearly shown in FIG. 2a:
The microcontroller 20 initiates the trigger signal 34 to the gate 24 of the triac 18 at the first zero crossing 28 of the AC half cycle 26 so as to deliver power to the AC load 12 through the triac. The timer is started when the trigger signal is initiated at the first zero crossing.
The trigger signal 34 is terminated proximate a halfway point 36 within the AC half cycle 26, which is in advance of the subsequent zero crossing 30 thereof. Terminating the trigger signal in this manner ensures that the triac 18 will be switched to a high impedance state when a current level through the triac drops to a value below a minimum level required to maintain the triac in the conductive state. As such, the trigger signal 34 is sustained for at least one-eighth of the AC half cycle 26 so as to ensure the current level through the triac 18 has exceeded the minimum level required to maintain the triac in the conductive state.

After the subsequent zero crossing 30, the timer continues to progress through the remaining 0.37 milliseconds of the predetermined time interval. At an expiration 38 of the predetermined time interval shown in FIG. 2a, the microcontroller 20 obtains a reading of the voltage across the terminals 22 of the triac 18. The reading provides information as to the load type of the AC load 12. The load type is formally determined by comparing the reading to an expected value 40, shown in FIG. 2b, that the reading would have if the AC load were of a known type. As such, the expected value is based on a simplest case in which the AC load is predominantly resistive, which is shown by the voltage waveform 32 of the voltage across the triac in FIG. 2b; in this simplest case, the voltage across the triac 18 has a magnitude of 24 V at the expiration 38 of the predetermined time interval, which is the same as a value of the voltage of a 120 V (RMS) AC power source at the expiration of the predetermined time interval given in FIG. 2a.

Certain facts about operation and behaviour of the circuit 10 in response to the trigger signal 34 that is applied to the gate 24 of the triac 18, as described earlier, afford confidence in knowing the expected value 40. Firstly, it is important to realize that the voltage across the terminals 22 of the triac is near zero for a duration during which same is in the conductive state 42. As such, any impedance of the triac in the conductive state is negligible compared to the impedance of the AC load 12. Secondly, when the triac is in the high impedance state, the high impedance of the triac therein dominates the combined impedance of the triac in series with the AC load so that a majority, if not all, of the voltage of the AC power source is observed across the terminals of the triac. A leakage current may be present even when the triac is in the high impedance state, producing a voltage across the terminals of the AC load that is significantly smaller than the voltage across the AC load when the triac is in the conductive state. As such, the voltage across the terminals of the triac in the high impedance state will be influenced both by the AC power source 14 and any voltage across the terminals of the AC load 12. For this reason, the predetermined time interval is sufficiently long so that the expiration 38 of the predetermined time interval is after the subsequent zero crossing 30 of the AC half cycle. Furthermore, the predetermined time interval is selected shorter than three-halves of a duration of the AC half cycle 26 so that effects of the load type on the voltage across the triac 18, due to any voltage across the AC load 12 after the AC half cycle, can still be observed when the reading is obtained. In one embodiment, the predetermined time interval is shorter than eleven-eighths of a duration of the AC half cycle.

With the above understanding of the triac 18 in mind, the expected value can be accurately and precisely predicted because of the voltage-current characteristics of a predominantly resistive AC load and because the trigger signal 34 is applied in such a way so as to limit the triac to conducting in a first direction of current flow within a conduction cycle of the triac. As used herein, conduction cycle refers to a period in which the triac transitions from the high impedance state to the conductive state, remains in same, and then transitions back to the high impedance state. Firstly, a current through the predominantly resistive AC load is in phase with the voltage across the AC load 12. Consequently, the conduction cycle of the triac will take place within the AC half cycle, between the first 28 and subsequent 30 zero crossings, with an end of the conduction cycle coinciding with the subsequent zero crossing as illustrated in FIG. 2b. Lack of an energy storage component in the predominantly resistive AC load means that the voltage across the triac 18, after the end of the conduction cycle, will closely follow same of the AC power source 14 as there will not be a significant voltage across the AC load once the triac is in the high impedance state. Thus, when the reading of the voltage of the triac is obtained at the expiration 38 of the predetermined time interval as shown in FIG. 2b, the reading has a magnitude of 24 V, which is the same as the magnitude of the value of the voltage of the 120 V (RMS) AC power source at 0.37 milliseconds into a subsequent AC half cycle 26 as shown in FIG. 2a. As such, 24 V is used as the expected value 40, i.e., a reference point, to which readings are compared. Since few loads are purely resistive because all loads have some degree of inductance or capacitance, comparison of the reading is made against a range of values around the expected value spanning from a lower range limit below the expected value and an upper range limit above the expected value to account for this non-ideality. A reading lying outside the range of values indicates a load that is predominantly reactive, i.e., predominantly inductive or capacitive.

The voltage-current characteristics of predominantly reactive loads effect significantly different readings of the voltage across the triac 18 at the expiration 38 of the predetermined time interval, and on the basis thereof the AC load 12 is identified as either predominantly inductive or predominantly capacitive. When a steady state AC voltage is applied to a predominantly inductive load, a current waveform of current through the predominantly inductive load lags a voltage waveform 28 thereof in terms of phase. Although the test procedure does not occur in the steady state, similar relationships in phase between the voltage and current waveforms are observed. For this reason, if the AC load is predominantly inductive, the triac remains in the conductive state even after the subsequent zero crossing 30 of the AC half cycle 26 as shown in FIG. 2c because the AC load sustains the current level required to maintain the conductive state of the triac passed the subsequent zero crossing. Though the length of time for which the triac conducts 42 after the subsequent zero crossing varies with an inductance of the AC load, the duration of the predetermined time interval is selected so that most inductive household loads will maintain the triac in the conductive state past the expiration 38 of the predetermined time interval. As such, the reading has a value near zero 44 or lower than the lower range limit at the expiration 38 of the predetermined time interval as in FIG. 2c when the AC load 12 is predominantly inductive.

When a steady state AC voltage is applied to a predominantly capacitive load, a current waveform of the current through the predominantly capacitive load leads a voltage waveform thereof in terms of phase. Reiterating that even though the test procedure does not occur in the steady state, similar relationships in phase between the voltage and current waveforms are observed. For this reason, if the AC load 12 is predominantly capacitive, the triac 18 switches into the high impedance state prior to the subsequent zero crossing 30 of the AC half cycle 26 as shown in FIG. 2d because the current level through the AC load is near zero when the voltage across the AC load is approximately at maximum magnitude. Ideally, duration of conduction in the first direction of current flow is longer than the duration for which the trigger signal 34 is sustained so that the trigger signal is terminated before the current flow switches to a second direction thereof; in this scenario, the triac definitely switches to the high impedance state after conducting in the first direction of current flow. Though the length of time for which the triac conducts 42 after the first zero crossing 28 varies with a capacitance of the AC load 12, the capacitance of the AC load causes same to maintain a voltage even after the triac switches to the high impedance state. The voltage of the predominantly capacitive AC load due to the charge stored thereon has an effect of making the voltage across the triac appear like the voltage of the AC power source in FIG. 2a has advanced in time as shown in FIG. 2d. This advancing effect remains apparent for at least a period of time between switching to the high impedance state until the expiration 38 of the predetermined time interval, so that the reading will have a value 46 which has a magnitude greater than the upper range limit as illustrated in FIG. 2d. The advancing effect on the voltage of the AC power source 14 remains until the charge stored on the AC load 12 is depleted and predominantly capacitive impedance of the AC load is rendered insignificant compared to the high impedance of the triac in the high impedance state. However, the duration of the predetermined time interval is selected so that most capacitive household loads maintains the charge stored thereon until after the expiration 38 of the predetermined time interval.

The final step of the test procedure is to formally determine the load type of the AC load 12. This step is implemented by the microcontroller 20, which also has routines programmed to determine the load type of the AC load based on the reading obtained at the expiration 38 of the predetermined time interval. As mentioned earlier, the step of determining the load type includes comparing the reading to the range of values around the expected value 40 of 24 V. Thus, finding that the reading has a value which lies within the range of values identifies the load type as predominantly resistive. Alternatively, finding that the reading has a value that lies outside the range of values identifies the load type as predominantly reactive. If the value of the reading has a magnitude that exceeds the upper range limit, the load type is identified as predominantly capacitive. Typical household loads which are predominantly capacitive include CFLs. In addition, if the value of the reading has a magnitude below the lower range limit, the load type is identified as predominantly inductive. Typical household loads which are predominantly inductive include bathroom motor fans and ballasts of fluorescent tubes.

In summary, the test procedure is based on the principal that the load type affects a duration of conduction of the triac 18 in the first direction of current flow, which varies because the three main load types have different voltage-current characteristics. As such, the arrangement of the trigger signal 34 as in FIG. 2a effects conduction of current in only the first direction of current flow, so that any AC load 12 which is predominantly reactive can establish a net stored charge by the end of the conduction cycle. Furthermore, readings of the voltage across the triac 18 can be obtained to surmise when the triac switched into the high impedance state as a means of estimating the duration of the conduction cycle because measuring current levels through the circuit 10 is impractical.

Alternative embodiments may exist in which the circuit 10 is not used solely for purposes of performing the test procedure, but also to deliver power to the AC load 12 through the triac 18 when the circuit is in an ON mode. In such embodiments, the test procedure is performed every time power is to be applied to the AC load, i.e., whenever the triac is switched into the conductive state. As such, further to the test procedure, the results thereof may be applied by enabling or disabling a dimming function programmed into the microcontroller, in which the triac 18 is operated in a manner delivering phase-delayed power to the AC load 12. As such, after having determined that the load type is predominantly resistive, the microcontroller 20 enables the dimming function because the AC load is able to tolerate phase-delayed power. In contrast, having determined that the load type is predominantly reactive, the microcontroller disables the dimming function because the AC load is unable to tolerate phase-delayed power. As such, the triac is prevented from operating in a load-dimming manner, and instead can only be used to deliver full power to the AC load.

It is important to recognize that certain modifications may be made to the test procedure involving the circuit 10 without deviating from the spirit of the circuit and the method. For example, the first zero crossing 28 is that of a positive AC half cycle 26 in the preferred embodiment; however, the trigger signal 34 could be initiated at the first zero crossing of a negative AC half cycle, in which case the triac 18 would conduct in an opposite direction of current flow during the test procedure. Notwithstanding the change in direction of current flow, which may affect the configuration of the circuit in the event that a unidirectional electronic switch is used in the test circuit instead of the triac of the preferred embodiment, the test procedure remains the same. Also, the test procedure will work with a 50 Hz electrical system and with different AC voltage levels when the proper adjustments are made to the test criteria, which would be reflected mainly in the duration of the predetermined time interval and the expected value (and range of values) to which the reading is compared.

Since various modifications can be made in my invention as herein above described, and many apparently widely different embodiments of same made, it is intended that all matter contained in the accompanying specification shall be interpreted as illustrative only and not in a limiting sense.

1. A circuit for determining load type of an electrical AC load that is receiving power from an AC power source through an AC power line, the circuit comprising:
an electronic switch connected in series between the AC power source and the AC load;
a triggering device configured to provide a trigger signal to switch said electronic switch to a conductive state; and
a measuring device arranged to obtain a reading of a monitored condition that is indicative of a voltage across terminals of the electronic switch;
wherein the triggering device is arranged to, within an AC half cycle of a voltage of the AC power source, initiate the trigger signal proximate a first zero crossing of the AC half cycle so as to deliver power to the AC load through said electronic switch, subsequently terminate the trigger signal in advance of a subsequent zero crossing of the AC half cycle so that the electronic switch will be switched to a high impedance state when a current level through the electronic switch drops to a value below a minimum level required to maintain the electronic switch in the conductive state; and
wherein the measuring device is arranged to obtain the reading after said subsequent zero crossing, the reading having a value based on which the load type of the AC load is determined.

2. The circuit according to claim 1, wherein the monitored condition is a voltage across the terminals of the electronic switch.

3. The circuit according to claim 1, further comprising a timer configured to measure a predetermined time interval, an expiration of which initiates the reading taken by the measuring device.

4. The circuit according to claim 3, wherein the predetermined time interval is sufficiently long so that the expiration of the predetermined time interval is after said subsequent zero crossing.

5. The circuit according to claim 3, wherein the triggering device is arranged to initiate the trigger signal at a start of the predetermined time interval.

6. The circuit according to claim 1, wherein the triggering device is arranged to sustain the trigger signal for at least one-eighth of the AC half cycle.

7. The circuit according to claim 1, wherein the triggering device is arranged to initiate the trigger signal at the first zero crossing of the AC half cycle.

8. The circuit according to claim 1, wherein the triggering device is arranged to terminate the trigger signal approximately halfway through the AC half cycle so as to limit the triac to conducting in a first direction of current flow within a conduction cycle of the electronic switch.

9. The circuit according to claim 1, further comprising a computing device which comprises a processor and a computer readable memory coupled to said processor and having stored thereon statements and instructions for execution by the process that, when executed, perform a test routine which includes a step of determining the load type based on the value of the reading.

10. The circuit according to claim 9, wherein the computer readable memory and the statements and instructions stored thereon are configured to include a timer function in the test routine that measures a predetermined time interval, and a measurement function that is initiated by expiry of the predetermined time interval to obtain the reading.

11. A method for determining load type of an electrical AC load that is receiving power from an AC power source through an AC power line in a circuit, the circuit further comprising an electronic switch which is connected in series between the AC power source and the AC load; a triggering device; and a measuring device;
the method comprising the following steps:
within an AC half cycle of a voltage of the AC power source, initiating a trigger signal of the triggering device proximate a first zero crossing of the AC half cycle, the trigger signal switching the electronic switch to a conductive state so as to deliver power to the AC load through said electronic switch;
terminating the trigger signal before a subsequent zero crossing of the AC half cycle so that the electronic switch will be switched to a high impedance state when a current level through the electronic switch drops to a value below a minimum level required to maintain the electronic switch in the conductive state;
after said subsequent zero crossing, obtaining a reading of a monitored condition that is indicative of a voltage across terminals of the electronic switch;
based on the reading, determining the load type of the AC load.

12. The method according to claim 11, wherein the step of determining the load type comprises comparing the reading to a range of values around an expected value for a predominantly resistive load, the range of values spanning from a lower range limit below the expected value and an upper range limit above the expected value.

13. The method according to claim 12, wherein the step of determining the load type further comprises finding that the reading has a value which lies within said range of values, and on the basis thereof identifying the load type as predominantly resistive.

14. The method according to claim 13, wherein when said electronic switch is operable to deliver phase-delayed power to the AC load in a first mode of operation, and having determined that the load type is predominantly resistive, the method further comprises the step of switching to the first mode of operation.

15. The method according to claim 12, wherein the step of determining the load type further comprises finding that the reading has a value that lies outside said range of values, and on the basis thereof identifying the load type as predominantly reactive.

16. The method according to claim 15, wherein when said electronic switch is operable to deliver phase-delayed power to the AC load in a first mode of operation, but not in a second mode of operation, and having determined that the load type is predominantly reactive, the method further comprises the step of switching to the second mode of operation.

17. The method according to claim 15, wherein the step of finding that the reading has a value that lies outside said range of values comprises finding that the value of the reading has a magnitude that exceeds the upper range limit, and on the basis thereof identifying the load type as predominantly capacitive.

18. The method according to claim 15, wherein the step of finding that the reading has a value that lies outside said range of values comprises finding that the value of the reading has a magnitude below the lower range limit, and on the basis thereof identifying the load type as predominantly inductive.

19. The method according to claim 11, wherein the triggering device sustains the trigger signal for at least one-eighth of a duration of the AC half cycle.
